(19) United States
(12) Patent Application Publication
(10) Pub. No.: US 2005/0000452 A1
(43) Pub. Date: Jan. 6, 2005

(54) Electromagnetic rotation of platter

(76) Inventor: Olof Claes Erik Kordina, Butler, PA (US)

Correspondence Address: Joan T. Kluger, Esquire;IP Department, Schnader Harrison Segal & Lewis LLP, 1600 Market Street, Suite 3600, Philadelphia, PA, 19103, US

(21) Appl. No.: 10/846,338

(22) Filed: May 13, 2004

Related U.S. Application Data
(60) Provisional application No. 60/471,157, filed on May 16, 2003.

(51) Int. Cl. C23C 16/00

(52) U.S. Cl. 118/728

(57) ABSTRACT

A method of rotation of a material formation platter and a rotating platter wherein the platter is subjected to a first magnetic field and a second magnetic field at an angle to the first magnetic field, thereby causing the platter to rotate.

This application is based on the provisional application having Ser. No. 60/471,157, filing date of May 16, 2003, and entitled Electromagnetic Rotation of Graphite Platter.

### FIELD OF THE INVENTION

The invention relates to methods for rotating samples during material formation, and is particularly applicable to epitaxial growth.

### BACKGROUND OF THE INVENTION

Epitaxy is used to grow layers of materials on substrates, such as in semiconductor chip fabrication. It is desirable to rotate the substrate to obtain better material uniformity. There are various ways of achieving rotation during growth processes. One is a straightforward motor driven rotation that requires complicated constructions with gears and feed-throughs. This solution often generates dust and is difficult to manage.

An improved method is known as gas foil rotation. FIG. 1 depicts a prior art susceptor 100 used in the gas foil rotation method. Susceptor 100 includes a susceptor base 102 and a platter 104. Platter 104 is shown raised from base 102 to reveal the rotation mechanism. During epitaxial growth, however, platter 104 is in close proximity to base 102.

Samples upon which epitaxial layers will be grown are placed in recessed areas 106. Platter 104 is rotated to facilitate uniform epitaxial growth. Rotation is accomplished by forcing a gas, such as air, into opening 108 causing platter 104 to ride on a gas layer. The gas exits base 102 at openings 110 then travels along channels 112, causing platter 104 to rotate.

Problems are associated with the gas foil rotation method. It is not possible to sufficiently control the speed of the system. The speed depends significantly on the condition of the system and, to a minor extent, on the gas flow. If the gas flow is too high, wobbling will occur, and if too low, the platter will no longer levitate. Accordingly, there is a need for a platter rotation method that allows effective control of speed, and provides stable rotation.

### DESCRIPTION OF THE DRAWINGS

The invention is best understood from the following detailed description when read with the accompanying drawings.

FIG. 1 depicts a prior art susceptor.

FIG. 2 depicts a susceptor according to an illustrative embodiment of the invention.

FIG. 3 depicts a reactor according to an illustrative embodiment of the invention.

FIGS. 4A-C depict a rotational mechanism according to an illustrative embodiment of the invention.

### SUMMARY OF THE INVENTION

An inventive method is disclosed for rotation of a material formation platter. The method includes subjecting the platter to a first magnetic field and a second magnetic field at an angle to the first magnetic field, thereby causing the platter to rotate. In an illustrative embodiment of the invention, the magnetic fields are generated by one or more coils. Advantageously, in preferred embodiments, the components used to generate rotation may also be used to provide heat to the platter or material disposed thereon.

The rotating platter device and methods are suitable for use in processes such as epitaxial growth; ion implantation; oxidation and diffusion. The invention includes a material or semiconductor device formed by the inventive a process or using the inventive apparatus.

### DESCRIPTION OF THE INVENTION

The invention provides a mechanism to rotate and control the rotational speed of a susceptor platter that takes advantage of the same type of components commonly used to heat the susceptor. The susceptor is typically heated to facilitate material growth during epitaxy. Heating is normally accomplished using a coil and a high frequency generator. The generator and the coil induce an oscillating magnetic field that induces oscillating current loops, which heat the susceptor through ohmic losses. This is known as induction heating.

Advantageously, it has been found that the electromagnetic forces generated to heat the susceptor can also be utilized to rotate and control the rotation of the susceptor platter. FIG. 2 depicts a susceptor 200 according to an illustrative embodiment of the invention. Susceptor 200 has a base 202 and platter 204. Platter 204 rotates with respect to base 200 during material formation processes. Optionally a gas flow into the interface between base 202 and platter 204 may be used to reduce friction that would be present between platter 204 and susceptor base 202. In an illustrative embodiment, gas is forced into inlet 206, and out of outlets 208 to lift platter 204 off base 202. Any other mechanism to sufficiently reduce friction that is compatible with the susceptor use is within the spirit and scope of the invention, such as low friction material components. Such other mechanisms may eliminate the need for gas flow into inlet 206. Furthermore, two or more friction-reducing mechanisms may be used with one another.

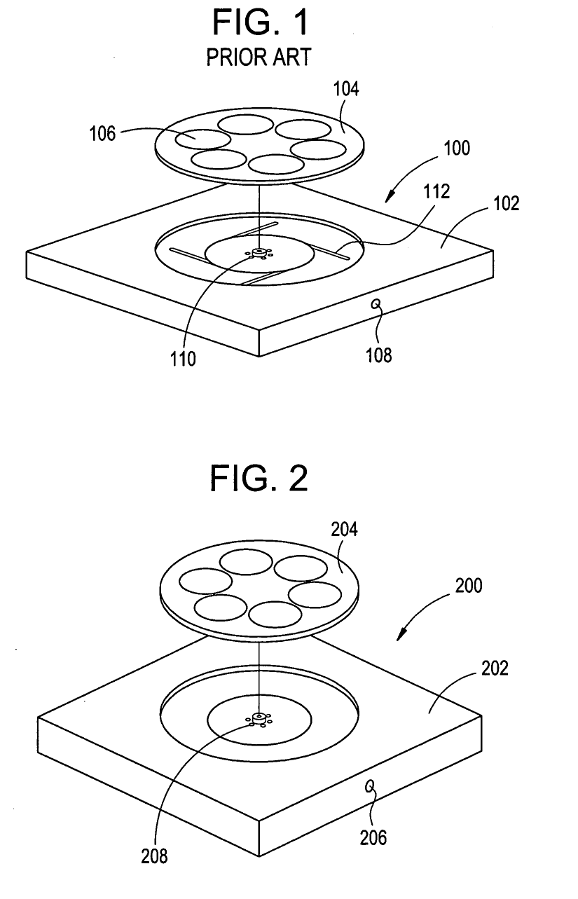

Channels 112, as shown in FIG. 1 are noticeably absent from FIG. 2, as they are not needed as a mechanism of rotation. They could, however, be used in conjunction with the rotation mechanism of the present invention that will now be described.

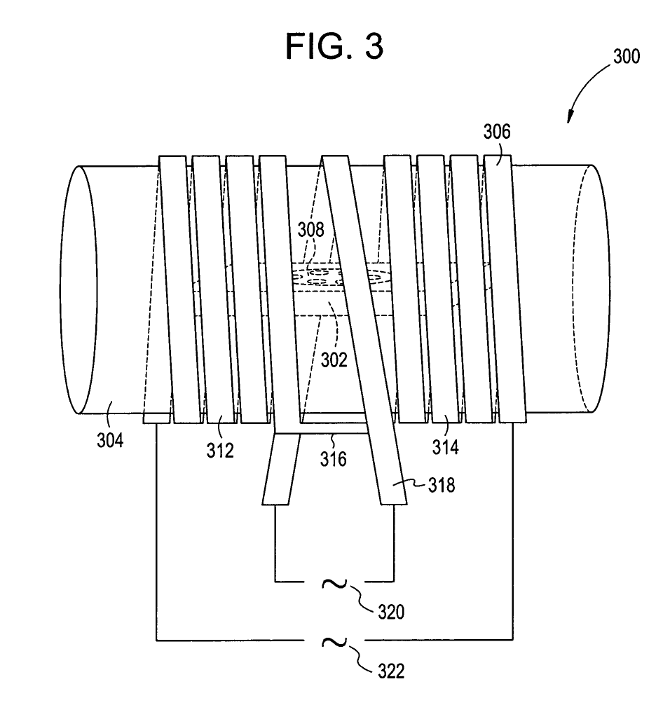

FIG. 3 depicts a portion of an epitaxial growth chamber 300 according to an illustrative embodiment of the invention. Susceptor 302 is within a tube 304, preferably constructed of quartz to contain process gases. Coil 306 is wrapped around tube 304. An electric charge traveling through coil 306 creates a magnetic field to heat susceptor 302. Coil 306 is in two sections 312 and 314, connected by length 316. This provides space for a second coil 318 that can be used to affect rotation of platter 308. A two-coil configuration provides one coil for susceptor heating and a second coil that can be adjusted to produce platter rotation. Preferably coil 318 is wrapped over length 316. Additionally, it is preferred to use two sources of electrical current, one for each of coils 306 and 318. As current level affects both temperature and rotational speed, separate current sources allow independent adjustment of these two quantities. Application of current is shown at 320 and 322. Current sources may be for example, RF generators.

Preferably the current sources are phase locked, with a variable phase angle. The current and the induced magnetic field will be oscillating. When the current and magnetic fields oscillate it is advantageous to have the magnetic fields oriented in the proper direction so that the platter does not rotate in one direction one moment and in another the next. Variable phase angle can also be important for speed control purposes. It is believed that all angles between 0° and 180° will provide rotation in first one direction, slowing down to zero and then rotating in the other direction. Rotational speed is dependent on variables such as, phase angle, coil turns per linear distance, and power output of the generator.

If a single coil is used for both heating and rotation, which is within the scope of the invention, a balance must be achieved between heat generated and rotational speed desired when choosing the optimum number of coil turns per linear distance. Although a single coil design would simplify the apparatus, it would be more difficult to achieve both optimum temperature and rotational speed.

The rotational speed can be controlled through the power input of the generator. The magnetic field will in fact induce a small component, which creates a force that brings platter 308 to rotate. Thus, even if no channels are present as in gas foil rotation, it is possible to cause platter 308 to rotate by rotational forces created from the induction heating mechanism. The speed can be controlled by the power input and/or the angle (or spread or coil loop density) of the coil. The greater the power, the faster the speed and the greater the angle, the faster the speed. In a preferred embodiment of the invention, platter 308 is levitated with gases, as in gas foil rotation.

The platter is preferably graphite but may be made of a metal such as molybdenum, tungsten, or tantalum. Metals thus in general, by virtue of their conductivity and their susceptibility to induction heating, are suitable platter materials. Metals are also suitable for their ability to become magnetized and thus spin when exposed to a second magnetic field at angle thereto, according to the present invention. (As used herein, “subjecting the platter to a magnetic field” includes magnetizing the platter itself.)

The preceding description presented illustrative embodiments of the invention to provide an understanding of the invention as it relates to particular applications. Following is a broader description of the invention, the scope of which will include further applications.

The method and apparatus can be applied to any deposition or growth technique or other material modification processes where sample rotation is desired. Processes include, for example, oxidation, diffusion, and ion implantation. An example of an epitaxy process for which embodiments of this invention can be used is chemical vapor deposition. Other applications, in particular where an object must be heated and rotated, are within the spirit and scope of the invention.

The invention includes an apparatus for rotating a sample and the method of rotation. The invention further includes an epitaxial growth method using the rotational methods described herein. Still further, the invention includes a semiconductor device having a material layer fabricated using devices, or methods of the invention.

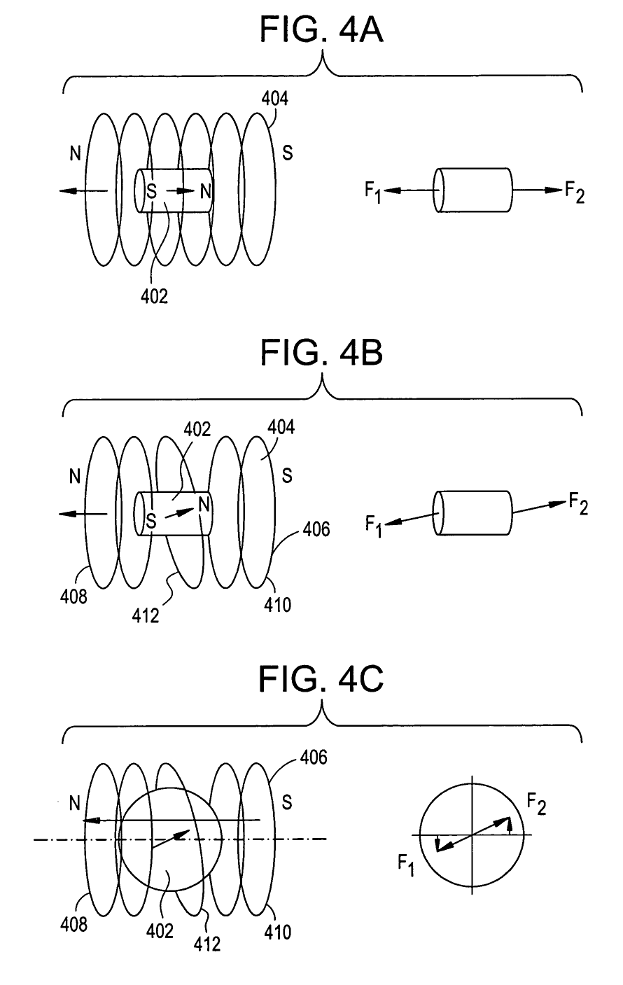

Rotation of the platter is achieved by subjecting it to at least two magnetic fields having different directions, i.e., at an angle to one another. FIGS. 4A-4C illustrate the inventor's belief of the mechanism by which rotation is caused. FIG. 4A shows a cylinder 402 in a perfect coil 404, i.e. having uniform coil diameter and spacing. Note that the spacing of the coil is directly related to the angle of the coil with respect to a longitudinal line passing through the cylinder. When current is passed through coil 402, a magnetic field is generated. The cylinder may be magnetized by the surrounding field. As both fields are created by the same coil with the same coil spacing, the magnetic field of the cylinder and that which surrounds the cylinder are directed along the same longitudinal line, as shown by the arrows in FIG. 4A. Accordingly, cylinder 402 will remain stationary within coil 404. In a perfect coil with the cylinder exactly in the center, the cylinder will not move. F₁ will be equal to F₂.

FIG. 4B shows the same cylinder 402 in a coil 406, which has its center part 412 stretched out. The coil angle in coil section 412 is different than the coil angle in the coil's outer sections 408 and 410. It is noted that coil sections 408, 410 and 412 can have any number of loops each. The magnetic field in the whole coil 404 seen as a unit is still parallel with the coil axis though it may be somewhat distorted, but it is essentially the same as in the case shown in FIG. 4A in a macroscopic sense. However, once at a level close to where cylinder 402 is, the magnetic field will be skewed somewhat by the elongated coil, which results in a magnetic field in cylinder 402 which is opposing the field created by coil section 412. With this magnetic field in cylinder 402 and the main magnetic field of the coil, which is parallel to the coil axis, forces are created that are at an angle and that create a torque on the piece.

FIG. 4C is the same case as depicted in FIG. 4B but with the rotating platter seen from above. The forces are skewed and are shown broken down into a component parallel to the coil axis and one perpendicular. The component of the force parallel to the coil axis is cancelled by the force on the other side but the perpendicular component of both forces creates a torque that rotates the platter. This torque causes the platter to rotate.

In summary, the method of rotating the platter includes subjecting the platter to a first magnetic field and a second magnetic field that is at an angle to the first magnetic field. The description above provides examples using one or two coils to create the magnetic fields. It will be understood by those skilled in the art that the magnetic fields can be created by any other mechanism that can be used in the environment in which the apparatus or method will be used. This can include, for example bar magnets, or other electro or non-electromagnets.

When using two coils or a single coil, one or more of the following characteristics may be varied to achieve differently directed magnetic fields: coil material, coil cross-sectional diameter; coil loop diameter and coil loop density (angle). Coils or other magnetic field producing components may also be used to heat the susceptor, which may simplify device designs.

Rotational speed of the platter may be controlled by a rotational speed component that controls a variable that affects speed by altering the magnetic field in some manner. Examples of variables that can be changed include, current or power to at least one of the coils or other magnetizing component, component material and dimensions, and number of coil turns per linear distance in at least one of the coils.

Rotation can be improved by incorporating friction reducing methods or designs. As described above, gas flows may be introduced between the platter and other components to reduce friction. Alternatively, or in addition, one or more components may be formed with a material having a low coefficient of friction.

The rotating platter can be used in material growth processes, for example by positioning a substrate on the platter and performing a process selected from the group consisting of epitaxial growth; ion implantation; oxidation and diffusion. Any material fabricated at least in part by any of these or other processes using the rotating platter of the invention is within the scope of the invention.

In a broad sense the invention includes a rotation apparatus for use in a material formation process having a platter, a first magnetic field affecting the platter and a second magnetic field at an angle to the first magnetic field and also affecting the platter, thereby causing the platter to rotate.

When the inventive platter device is used for a material formation process it typically will be disposed within a chamber. The material formation process will take place in the chamber with the platter rotating at least during part of the formation process. As used herein “material formation” includes formation of material on a substrate, crystal formation and processes that created new characteristics in a material such as ion implantation.

While the invention has been described by illustrative embodiments, additional advantages and modifications will occur to those skilled in the art. Therefore, the invention in its broader aspects is not limited to specific details shown and described herein. Modifications, for example, to the configuration of the apparatus, the materials used and the processes to which the invention is applied, may be made without departing from the spirit and scope of the invention. Accordingly, it is intended that the invention not be limited to the specific illustrative embodiments, but be interpreted within the full spirit and scope of the claimed invention and equivalents thereof.

1. A method of rotation of a material formation platter, the method comprising:
subjecting the platter to a first magnetic field; and
subjecting the platter to a second magnetic field at an angle to the first magnetic field, thereby causing the platter to rotate.

2. The method of claim 1 wherein the first and second magnetic fields are generated by:
providing a single coil around the platter; and
applying a current to the coil;
wherein the first magnetic field is generated by a first coil section and the second magnetic field is generated by a second coil section, and wherein the first and second coil sections differ in one or more characteristics selected from the group consisting of coil material, coil cross-sectional diameter; coil loop diameter and coil loop density (angle).

3. The method of claim 2 wherein the first magnetic field is generated by a first coil section with a first coil loop density and the second magnetic field is generated by a second coil section having a second coil loop density.

4. The method of claim 2 wherein the coil also provides heat to the platter.

5. The method of claim 1 wherein the first and second magnetic fields are generated by:
providing a first coil around the platter;
applying a current to the first coil to generate the first magnetic field;
providing a second coil around the platter; and
applying a current to the second coil to generate the second magnetic field.

6. The method of claim 5 wherein the currents to the first and second coils are generated by first and second current sources, respectively.

7. The method of claim 5 wherein at least one of the coils also provides heat to the platter.

8. The method of claim 5 wherein sources providing the current to the first and second coils are phase locked.

9. The method of claim 8 wherein the phase angle between the current sources is variable.

10. The method of claim 2 further comprising controlling rotational speed of the platter by varying one or more of the following quantities, current to the coil and number of coil turns per linear distance in at least a portion of the coil.

11. The method of claim 5 further comprising controlling rotational speed of the platter by varying one or more of the following quantities, current to at least one of the coils, power to at least one of the coils and number of coil turns per linear distance in at least one of the coils.

12. The method of claim 1 further comprising:
reducing friction between the platter and a base on which the platter is disposed.

13. The method of claim 12 wherein the friction is reduced by flowing a gas between the base and platter.

14. The method of claim 12 wherein the friction is reduced by forming one or more components with a material having a low coefficient of friction.

15. The method of claim 1 further comprising:
positioning a substrate on the platter; and
performing a process selected from the group consisting of epitaxial growth, ion implantation, oxidation and diffusion.

16. A material formed at least in part by the method of claim 1.

17. An epitaxial layer fabricated at least in part by the method of claim 1.

18. A semiconductor device fabricated at least in part by the method of claim 1.

19. A rotation apparatus for use in a material formation process comprising:
a platter;
a first magnetic field affecting the platter;
a second magnetic field at an angle to the first magnetic field and also affecting the platter, thereby causing the platter to rotate.

20. The rotation apparatus of claim 19 comprising:
a single coil disposed around the platter and having a first coil section and a second coil section;
wherein the first magnetic field is generated by current transmitted through the first coil section and the second magnetic field is generated by current transmitted through the second coil section, and wherein the first and second coil sections differ in one or more characteristics selected from the group consisting of coil material, coil cross-sectional diameter; coil loop diameter and coil loop density.

21. The rotation apparatus of claim 20 wherein the first coil section has a first coil loop density and the second coil section has a second coil loop density.

22. The rotation apparatus of claim 20 wherein the coil also provides heat to the platter.

23. The rotation apparatus of claim 19 comprising:
a first coil disposed around the platter to which a current can be applied to generate the first magnetic field; and
a second coil disposed around the platter to which a current can be applied to generate the second magnetic field.

24. The rotation apparatus of claim 23 wherein the currents to the first and second coils are generated by first and second current sources, respectively.

25. The rotation apparatus of claim 23 wherein at least one of the coils also provides heat to the platter.

26. The rotation apparatus of claim 24 wherein the current sources are phase locked.

27. The rotation apparatus of claim 20 wherein the phase angle between the current sources is variable.

28. The rotation apparatus of claim 20 further comprising one or more rotational speed control components selected from the group consisting of current controller, power controller and coil turn per linear distance controller.

29. The rotation apparatus of claim 19 further comprising:
a base on which the platter is disposed; and
an inlet path along which a gas can flow to reduce friction between the base and platter.

30. The rotation apparatus of claim 1 further comprising:
a chamber disposed around the rotation apparatus in which a process selected from the group consisting of epitaxial growth, ion implantation, oxidation and diffusion can be performed.

31. A material formed at least in part using the rotation apparatus of claim 19.

32. An epitaxial layer fabricated at least in part using the rotation apparatus of claim 19.

33. A semiconductor device fabricated at least in part using the rotation apparatus of claim 19.
